(19) United States
(12) Patent Application Publication
(10) Pub. No.: US 2009/0056998 A1
(43) Pub. Date: Mar. 5, 2009

(54) METHODS FOR MANUFACTURING A SEMI-BURIED VIA AND ARTICLES COMPRISING THE SAME

(75) Inventors: Roger A. Booth, Jr., Wappingers Falls, NY (US); John R. Dangler, Rochester, MN (US); Matthew S. Doyle, Rochester, MN (US); Jesse Hefner, Rochester, MN (US); Thomas W. Liang, Rochester, MN (US); Ankur K. Patel, Rochester, MN (US); Paul Rudrud, Rochester, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/848,330

(22) Filed: Aug. 31, 2007

(51) Int. Cl. H05K 1/11; H05K 3/10

(52) U.S. Cl. 174/262; 29/852

(57) ABSTRACT

Disclosed herein is a method comprising drilling a first hole in a multilayered device; the multilayered device comprising a fill layer disposed between and in intimate contact with two layers of a first electrically conducting material; the fill layer being electrically insulating; plating the first hole with a slurry; the slurry comprising a magnetic material, an electrically conducting material, or a combination comprising at least one of the foregoing materials; filling the first hole with a fill material; the fill material being electrically insulating; laminating a first layer and a second layer on opposing faces of the multilayered device to form a laminate; the opposing faces being the faces through which the first hole is drilled; the first layer and the second layer each comprising a second electrically conducting material; drilling a second hole through the laminate; the second hole having a circumference that is encompassed by a circumference of the first hole; and plating the surface of the second hole with a third electrically conducting material.

### BACKGROUND

This disclosure relates to methods for manufacturing a semi-buried via and articles comprising the same.

A multilayered device such as a printed circuit board comprises a thin plate formed of multiple layers onto which chips and other electronic components, such as integrated circuits, are mounted. Computers comprise one or more boards, often called cards or adapters. Each layer of the printed circuit board includes metal paths ending in contact pads. An electronic device transfers signals to a network of metal paths through the contact pad to communicate over the metal paths with other electronic devices on the same or different layers of the substrate. A via structure extends through holes in the layers and interfaces with contact pads on different layers to allow signals to travel between layers through the via. In this way, the via provides a conductive path to communicate between conductive layers.

A forward current or signal transmitted from a source device on one layer to a target device on another will pass through the via. A return current will travel on one or more voltage layers, such as a ground layer adjacent to the signal path. The return current will attempt to follow the path closest to the original signal on the voltage layer to minimize the loop area. However, the return current may have to diverge from the closest path of the forward current to a structure, such as another via or a decoupling cap, in order to move from one voltage layer to another that is in communication with the source device. This divergence from the closest path following the signal trace path of the forward current increases the loop area of the forward and return currents. Increasing the loop area results in a corresponding increase in inductance and, hence, electronic emissions, i.e., noise. Such increased emissions and noise increases cross-talk, interferes with other signals in the system and promotes radiation from the card.

Thus, it is desirable to have an improved manufacturing technique for controlling the path of the return current in order to minimize inductance and electronic emissions and interference.

### SUMMARY

Disclosed herein is a method comprising drilling a first hole in a multilayered device; the multilayered device comprising a fill layer disposed between and in intimate contact with two layers of a first electrically conducting material; the fill layer being electrically insulating; plating the first hole with a slurry; the slurry comprising a magnetic material, an electrically conducting material, or a combination comprising at least one of the foregoing materials; filling the first hole with a fill material; the fill material being electrically insulating; laminating a first layer and a second layer on opposing faces of the multilayered device to form a laminate; the opposing faces being the faces through which the first hole is drilled; the first layer and the second layer each comprising a second electrically conducting material; drilling a second hole through the laminate; the second hole having a circumference that is encompassed by a circumference of the first hole; and plating the surface of the second hole with a third electrically conducting material.

Disclosed herein too is an article manufactured by the aforementioned method.

### BRIEF DESCRIPTION OF FIGURES

FIG. 1 depicts a multilayered device prior to drilling a hole through it;

FIG. 2 depicts the multilayered device after the drilling of the first hole;

FIG. 3 depicts the multilayered device after plating the surface of the first hole with the plating material, and filling the first hole with the fill material;

FIG. 4 depicts the lamination of the multilayered device;

FIG. 5 depicts the multilayered device of the FIG. 4 after drilling of the second hole and the plating of the surface of the second hole;

FIG. 6 depicts a multilayered device used for manufacturing a ground sleeve;

FIG. 7 depicts the multilayered device of FIG. 6 after the drilling of the first hole;

FIG. 8 depicts the multilayered device of FIG. 7 after plating the surface of the first hole with the plating material, and the filling the first hole with the fill material;

FIG. 9 depicts the multilayered device of FIG. 8 after the lamination;

FIG. 10 depicts the multilayered device of the FIG. 9 after drilling of the second hole and the plating of a surface of the second hole; and

FIG. 11 depicts the functioning of the multilayered device of FIG. 10.

### DETAILED DESCRIPTION

The use of the terms “a” and “an” and “the” and similar references in the context of describing the invention (especially in the context of the following claims) are to be construed to cover both the singular and the plural, unless otherwise indicated herein or clearly contradicted by context. The modifier “about” used in connection with a quantity is inclusive of the stated value and has the meaning dictated by the context (e.g., it includes the degree of error associated with measurement of the particular quantity). All ranges disclosed herein are inclusive of the endpoints, and the endpoints are independently combinable with each other.

Disclosed herein is a method for manufacturing a printed circuit board comprising a via that minimizes via-to-via coupling by forming a coaxial shield that is embedded in a card via. Disclosed herein too is a structure for an electrically conducting ring that encloses a single ended or differential pair on the external layers of the pad stack. The ring is plated with a magnetic slurry. The presence of the circular magnetic via ring provides a choke such that any high frequency noise on the signal line through the via can be reduced. In the differential case, the effect is similar to that of an external toroid.

In one embodiment, the via structure provides one or more paths for different arrangements of the signal and voltage (ground) layers to allow a return current to follow, i.e., shadow as closely as possible the signal trace of the initial forward current in order to minimize inductance and the loop area. The return current follows the signal trace of the forward current on the voltage layer due to the phenomena of mutual inductance where a return current is attracted to follow the closest plane to minimize inductance between the forward and return current. The via structure enables the return current to follow the path of minimum inductance by providing a via structure through which both a forward and return current may travel. This minimizes the radiation of emissions from the printed circuit board. Further, in exemplary embodiments the dielectric annular region and signal conductor are coaxial.

In another embodiment, the outside layer of the via can comprise a conductive structure that shields the circuit board from the current in the via. The aforementioned via structure permits the use of a dual current path via to replace decoupling circuits located on the printed circuit board for use by return paths. This via structure provides many advantages over the prior art use of decoupling circuits for the return current. The via design permits conductive lines or paths and contacts on the upper surface of the layers. The via signal conductor and dielectric annular region can be used to allow forward and return currents to move from a upper or lower surface of the printed circuit board to an upper or lower surface of the same printed circuit board.

The via structure may provide conductive regions to branch to multiple layers for the forward or return current exiting the via structure. In this way, the forward or return current can flow from one input layer to multiple output layers. The vias may be used to allow forward and return currents to flow between layers within an integrated circuit chip.

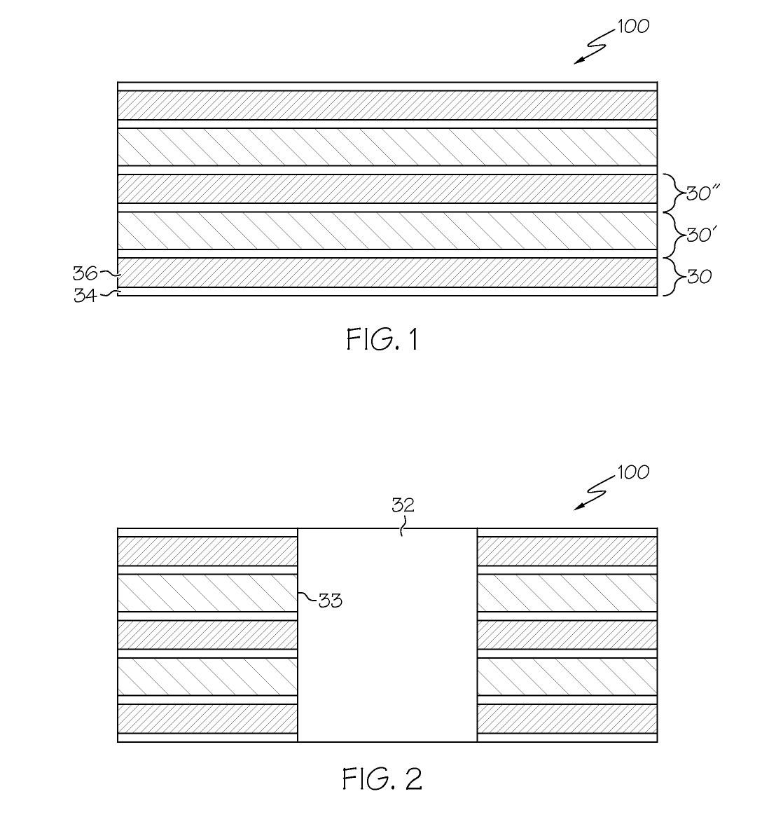

FIGS. 1-4 depict one method of manufacturing a buried magnetic sleeve in a multilayered device such as a printed circuit board. With reference now to the FIGS. 1 and 2, a multilayered device 100 comprises a single layer 30 or a plurality of layers 30, 30′, 30″, through which a first hole 32 is drilled. The first hole forms the basis for the via, which as defined herein, comprises a plated-through hole used for the interconnection of conductors on different sides or layers of the multilayered device. The multilayered device 100 as first received does not have the top and bottom layers. The top and bottom layers are disposed upon opposing faces of the multilayered device 100 later in the process as will be detailed below.

As is known in the art, each layer of the multilayered device comprises a conducting layer 34 and a fill layer 36. The conducting layer 34 generally comprises a first conducting material such as, for example, copper or a copper alloy, while the fill layer 36 can comprise a first fill material. The first fill material is generally fiberglass or fiberglass impregnated with an organic polymer. In one embodiment, alternating layers of the multilayered device can comprise fiberglass and fiberglass impregnated with an organic polymer respectively (i.e., a first layer comprises fiberglass, while a second layer that is adjacent to the first layer comprises fiberglass impregnated with an organic polymer, and so on).

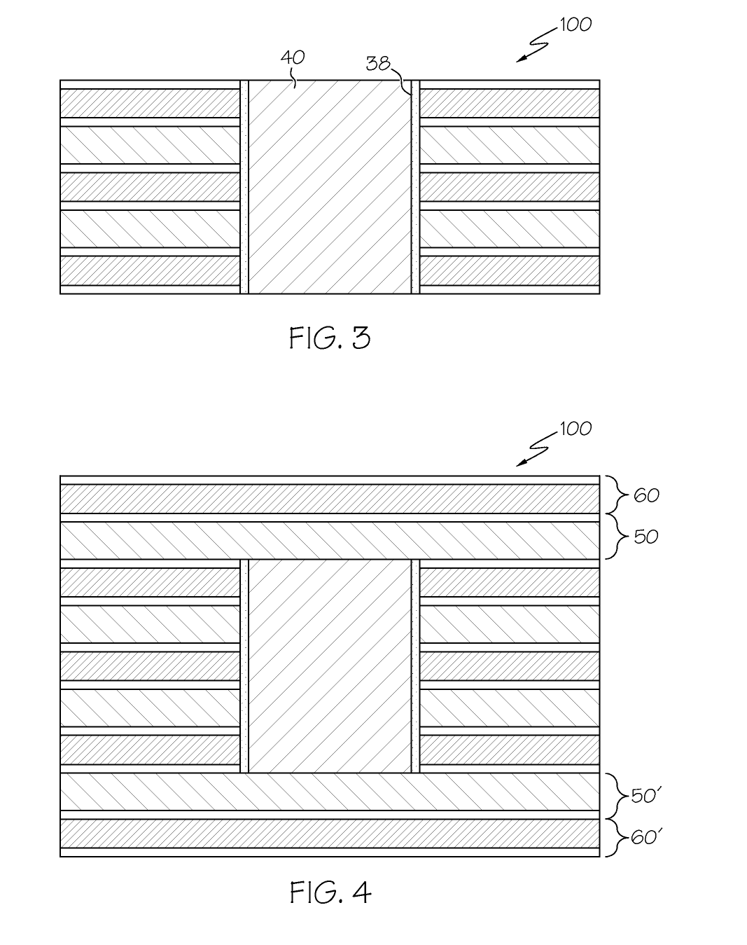

With reference now to the FIGS. 2 and 3, following the drilling of the first hole 32, the surface 33 of the first hole 32 is coated with a slurry that comprises a magnetic material. Suitable magnetic materials are ferromagnetic materials. Examples of ferromagnetic materials are iron, cobalt, nickel, gadolinium, or the like, or a combination comprising at least one of the foregoing materials. If a ferromagnetic material is not desired, the surface 33 of the first hole 32 may be coated with a second electrically conducting material. Following the deposition of the ferromagnetic material or the electrically conducting material, the multilayered device 100 may be subjected to heating in a vacuum in order to remove solvents and reactant by products from the slurry.

The first electrically conducting material and the second electrically conducting material may be the same or different.

The heating of the slurry produces a ferromagnetic layer or an electrically conducting layer 38 on the surface of the first hole 32. Following the formation of the ferromagnetic layer or an electrically conducting layer 38 on the surface 33 of the hole 32, the hole is filled with a second fill material 40. The second fill material comprises fiberglass or fiberglass impregnated with an organic polymer as depicted in the FIG. 3. The second fill material can be similar in composition or different in composition from that of the first fill material. An injection molding process can be used to deposit the second fill material into the first hole 32.

Following the deposition of the fill material into the first hole 32, additional layers 50, 60, 50′, and 60′ are laminated onto opposing surfaces of the multilayered device 100 as depicted in the FIG. 4. The additional layers may comprise a single layer or a plurality of layers. As can be seen in the FIG. 4, each additional layer comprises a fill layer disposed upon a conducting layer. The additional layers are laminated in such a manner that the conducting surfaces are disposed on the outside of the multilayered device.

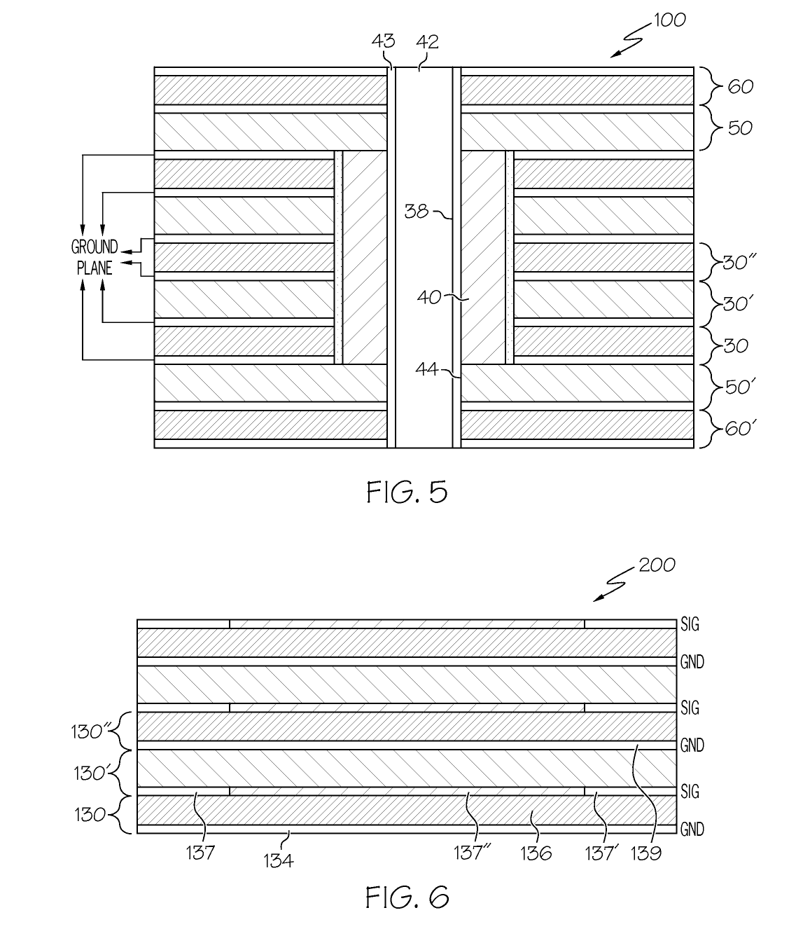

Following the lamination, as depicted in the FIG. 5, a second hole 42 or a plurality of holes (not shown) is drilled through the additional layers 50, 60, 50′, and 60′ and through the fill 40. When a single hole is drilled, the second hole 42 is drilled so as to be concentric with the first hole 32. In other words, the circumference of the second hole 42 lies within the circumference of the first hole 32. When a plurality of holes is drilled, it is generally desirable for the surfaces of each of the holes to be parallel to one another and to the surface of the surface of the first hole 32. The plurality of holes are generally drilled such that the circumference of each of the plurality of holes lies within the circumference of the first hole 32.

The surface 43 of the second hole 42 (or the surfaces of the plurality of second holes) is then coated with a conductive layer 44 to form the via. The conductive layer may comprise a third conductive material. The first conductive material, the second conductive material and the third conductive material may be the same or different. As noted above, the conductive layer 44 generally comprises a metal. Examples of suitable metals are copper, copper alloys, or the like.

The via generally has an aspect ratio of height to diameter of greater than or equal to about 5, specifically greater than or equal to about 10, and more specifically greater than or equal to about 20. As depicted in the FIG. 5, the electrical conducting layers 34 in layers 30, 30′, 30″, and so on, serve as ground planes to facilitate the dissipation of any induced return currents. The electrical conducting layers 34 in the top layers 50 and 60 and the bottom layers 50′ and 60′ facilitate the transfer of an electrical current from the top layer of the multilayered device to the bottom layer of the multilayered device through the via.

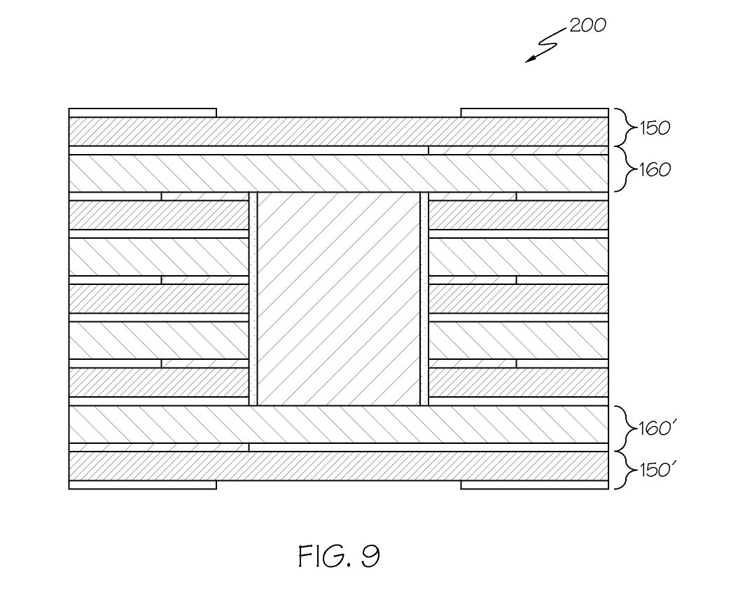

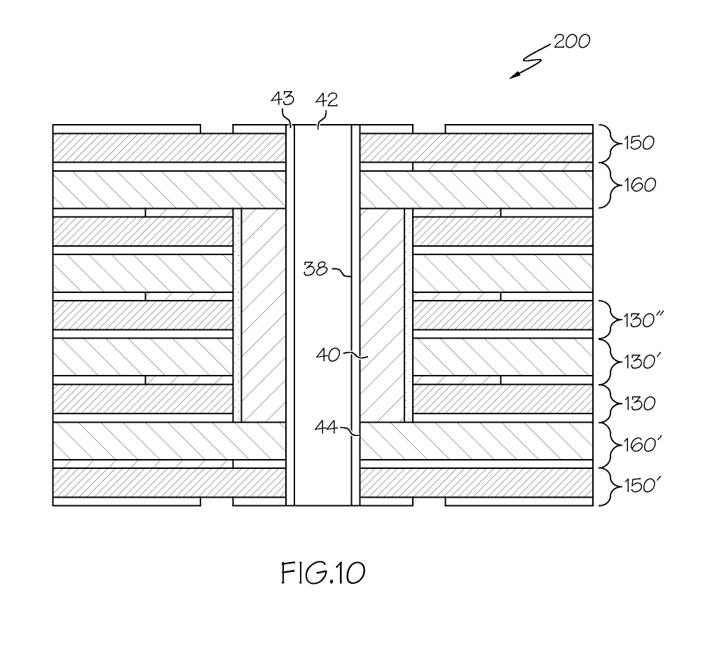

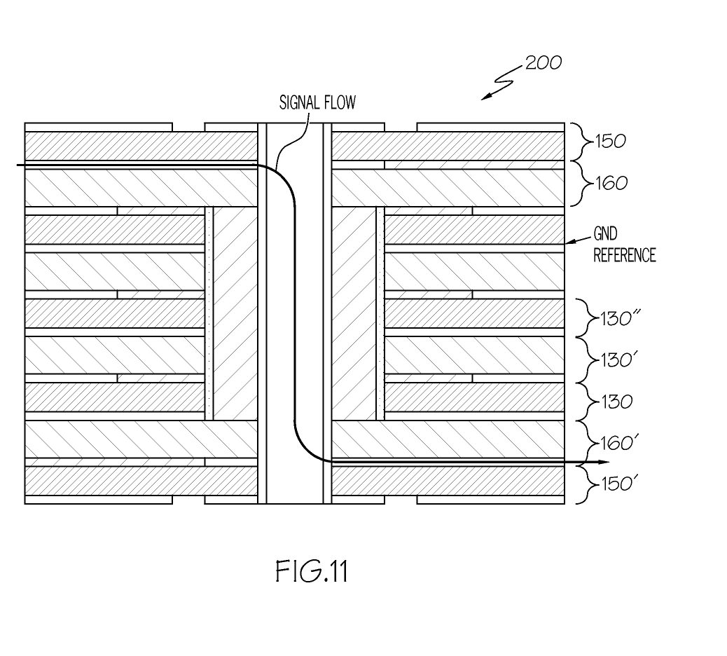

In another embodiment, in another method of manufacturing a ground sleeve, a multilayered device 200 comprises a single layer 130 or a plurality of layers 130, 130′, 130″, and so on, as depicted in the FIGS. 6-11. In the configuration depicted in the FIG. 6, the fill layer 136 of the layer 130 comprises a conducting layer 134 or ground layer disposed on one surface of the fill layer, with a signal layer 137 disposed upon an opposing surface of the same fill layer. Disposed upon the opposing surface of the signal layer 137 is the fill layer of the layer 130′, and disposed upon the opposing surface of the fill layer of the layer 130′, is a ground layer 139. The conducting layer 134 is generally electrically conducting along the entire surface of the fill layer, while the signal layer 137 is electrically conducting along only a portion of the surface of the fill layer. In other words, the signal layer comprises and electrically conducting portion 137′ and an electrically insulating portion 137″. The electrically insulating portion 137″ generally comprises the same composition as the fill layer. In this manner, alternating layers of the multilayered device share either a signal layer or a conducting layer.

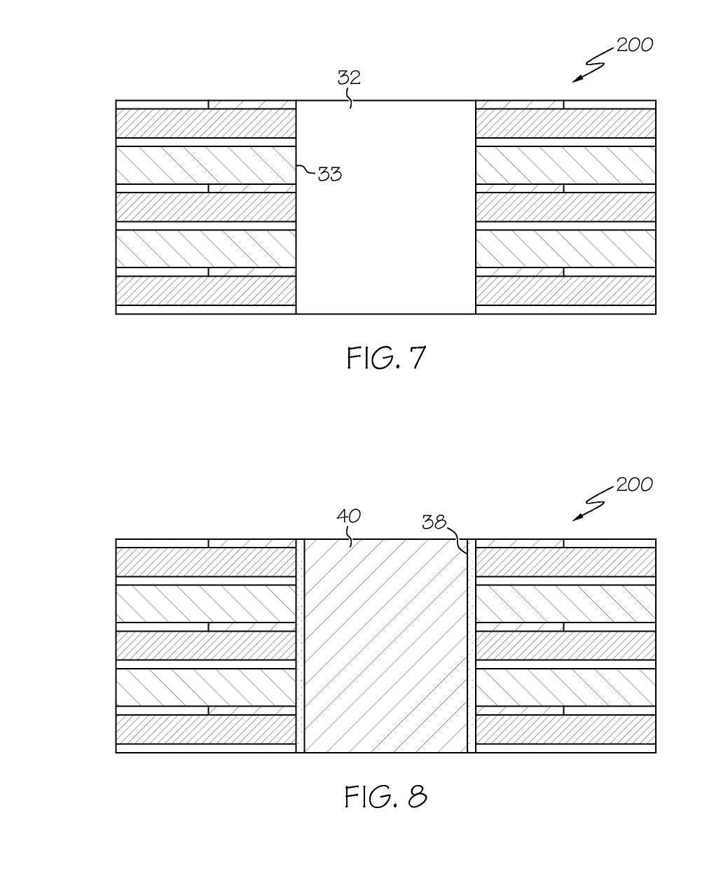

FIGS. 7-10 depict the method of manufacturing the ground sleeve, which is similar to the method depicted in the FIGS. 2-5 respectively. FIG. 11 depicts the functioning of the ground sleeve. In the FIG. 11, an electrical current transmitted to the top layers 150 and 160 of the multilayered device by an electronic device mounted on the multilayered device travels to the bottom layers 150′ and 160′ through the via. Induced return currents generated in the layers 130, 130′ and 130″ are transmitted to the ground.

In one embodiment, the multilayered device described above can be used as a part of a card for a computer. The card may include one or more electronic devices mounted onto the multilayered device, such as a semiconductor package comprising a package substrate.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method comprising:
drilling a first hole in a multilayered device; the multilayered device comprising a fill layer disposed between and in intimate contact with two layers of a first electrically conducting material; the fill layer being electrically insulating;
plating the first hole with a slurry; the slurry comprising a magnetic material, an electrically conducting material, or a combination comprising at least one of the foregoing materials;
filling the first hole with a fill material; the fill material being electrically insulating;
laminating a first layer and a second layer on opposing faces of the multilayered device to form a laminate; the opposing faces being the faces through which the first hole is drilled; the first layer and the second layer each comprising a second electrically conducting material; and
drilling a second hole through the laminate; the second hole having a circumference that is encompassed by a circumference of the first hole; and
plating the surface of the second hole with a third electrically conducting material.

2. The method of claim 1, wherein the magnetic material is a ferromagnetic material.

3. The method of claim 1, wherein the plating the hole with the slurry is followed by heating the multilayered device.

4. The method of claim 1, wherein the first layer and the second layer further comprise a fill layer; the respective fill layers being in communication with opposing faces of the multilayered device; the opposing faces being the faces through which the hole is drilled.

5. The method of claim 1, wherein the first electrically conducting material, the second electrically conducting material and the third electrically conducting material are the same.

6. The method of claim 1, wherein the first electrically conducting material, the second electrically conducting material and the third electrically conducting material are different from one another.

7. The method of claim 1, wherein the first electrically conducting material, the second electrically conducting material and/or the third electrically conducting material comprise copper or a copper alloy.

8. The method of claim 1, wherein the second hole is concentric with the first hole.

9. The method of claim 1, further comprising drilling a third hole; the third hole having a circumference that is encompassed by a circumference of the first hole.

10. The method of claim 9, wherein a surface of the third hole is parallel to a surface of the second hole.

11. The method of claim 9, wherein a surface of the third hole or a surface of the second hole is parallel to a surface of the first hole.

12. An article manufactured by the method of claim 1.
